(19) United States
(12) Patent Application Publication
(10) Pub. No.: US 2002/0093436 A1
(43) Pub. Date: Jul. 18, 2002

(54) Foldable membrane keyboard

(76) Inventor: Andy Lien, Pan-Chiao City (TW)

Correspondence Address: BACON & THOMAS, 4th Floor, 625 Slaters Lane, Alexandria, VA, 22314, US

(21) Appl. No.: 09/758,183

(22) Filed: Jan. 12, 2001

(51) Int. Cl. H03M 11/00; H03K 17/94; H01H 1/10; H05K 1/00

(52) U.S. Cl. 341/34; 200/512; 361/749

(57) ABSTRACT

A foldable membrane keyboard has folding lines for the keyboard to fold and pack in a holding case. The keyboard includes a bottom layer, a second conductive membrane layer (silver paste) located above the bottom layer, an insulation layer located above the second conductive membrane layer, a first conductive membrane layer located above the insulation layer, a top layer located above the first conductive membrane layer, and a transparent membrane layer. The insulation layer has a plurality of openings formed therein. The first and second conductive membrane layers have respectively a conductive circuit. The transparent membrane layer, top layer, first and second conductive membrane layers, insulation layer and bottom layer are bonded together at the peripheries by heat fusion to seal the first and second inductive membrane layer inside, except the transparent membrane layer which is bonded by heat fusion at three sides with one side opened. The foldable keyboard thus formed is watertight. The membrane keyboard may be folded in a compact size and be held in the holding case.

### BACKGROUND OF THE INVENTION

This invention relates to a foldable membrane keyboard and particularly a compact membrane keyboard that is capable of being folded and stored in a holding case to facilitate carrying and is watertight.

Nowadays slim and light has become a prevailing trend in the design and construction of technology products. However many personal electronic products now available in the market place still have the problem of too large size and are not convenient to carry around.

Some producers have developed and introduced portable keyboards that may be folded to multiple sections to facilitate carrying. They usually have a plurality of connection sections defined on a base board that are mapping against the button keys configuration and intervals. The circuit boards and button keys are made of pliable materials and are mounted on the connection sections. Below the base board, a substrate made of a pliable material is provided. The periphery of the substrate is formed in a jagged and interlocking cutting lines and is bordered by a protection frame. The keyboard thus made may be folded to a smaller size. However it still has a relatively big thickness and is not convenient for people to carry around in a bag. Furthermore, when the keyboard is unfolded for use, the bottom and periphery of the keyboard do not have support means at the folding sections. Hence the keyboard might get loose and moving at the folding sections when in use, and form different height levels at different sections. It makes user's fingers difficult to move around the keyboard during operation.

### SUMMARY OF THE INVENTION

It is therefore an object of this invention to resolve aforesaid disadvantages by providing a membrane keyboard that may be folded to a small size to facilitate carrying and is watertight.

Another object of this invention is to provide a membrane keyboard that may also be folded and contained in a holding case, and may be unfolded and held in the extended holding case for use.

A further object of this invention is to provide a membrane keyboard that has an interrupted device for stopping signal output from the keyboard so that the keyboard may be used as part of table top for holding documents and data without taking additional user's useful space (table top space).

Yet another object of this invention is to provide a membrane keyboard that has an exterior made of a soft material such as foam plastics, soft plastics, leather or the like.

Still another object of this invention is to provide a membrane keyboard that has a soft face panel which may be changed to different colors or patterns to suit users preference, and may further be printed with a plurality of key sets.

The membrane keyboard according to this invention includes a bottom layer, a second conductive membrane layer, an insulation layer, a first conductive membrane layer and a top layer that may be folded to a compact size, and be placed and contained in a holding case. It is easy to carry around and is watertight.

### BRIEF DESCRIPTION OF THE DRAWINGS

The invention, as well as its many advantages, may be further understood by the following detailed description and drawings, in which:

FIG. 1 is a perspective view of this invention.

FIG. 2 is an exploded view of this invention.

FIG. 3 is an exploded view of this invention extended for use.

FIG. 4A is a cross sectional view of this invention taken along line 4A-4A in FIG. 1.

FIG. 4B is a cross sectional view of this invention in use according to FIG. 4A.

FIG. 5 is a cross sectional view of this invention taken along line 5-5 in FIG. 1.

FIG. 6 is a schematic side view of this invention after folding in a holding case.

FIG. 7A is a fragmentary perspective view of a positional structure of the holding case according to this invention.

FIG. 7B is a fragmentary perspective view of another positional structure of the holding case according to this invention.

### DETAILED DESCRIPTION OF THE PREFERRED EMBODIMENT

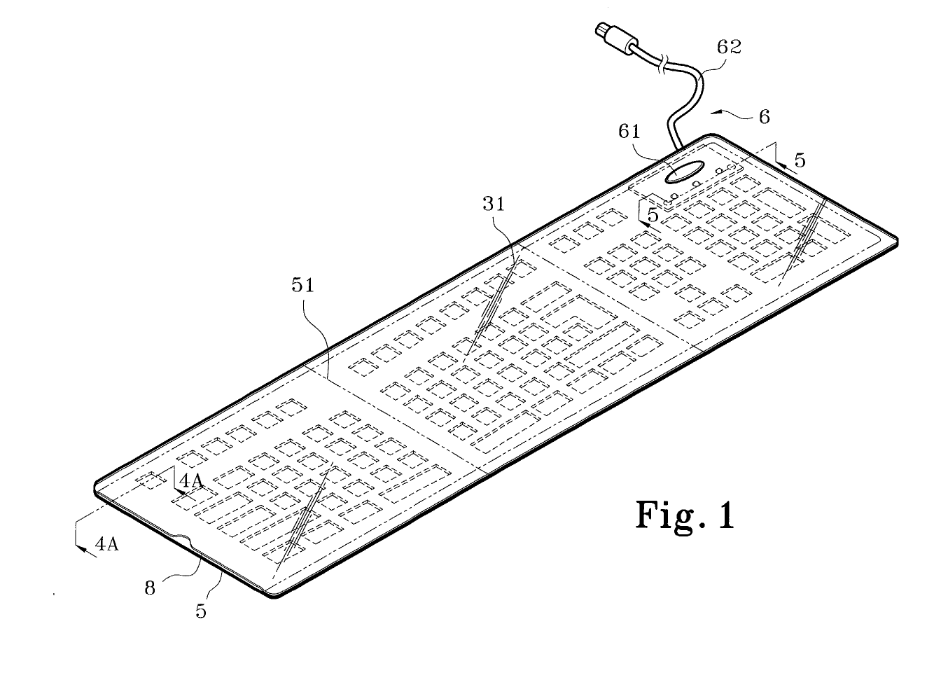

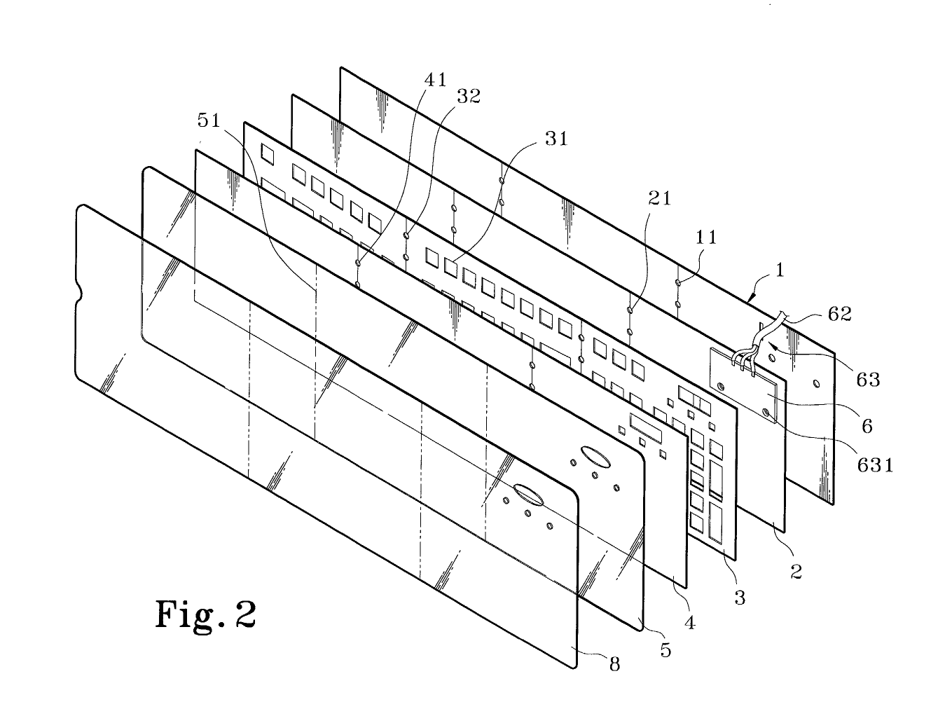

Referring to FIGS. 1, 2 and 3, the membrane keyboard according to this invention includes a bottom layer 1, a second conductive membrane layer 2, an insulation layer 3, a first conductive membrane layer 4, a top layer 5, a transparent membrane layer 8, and a holding case 7 that may be folded to a compact size to facilitate carrying.

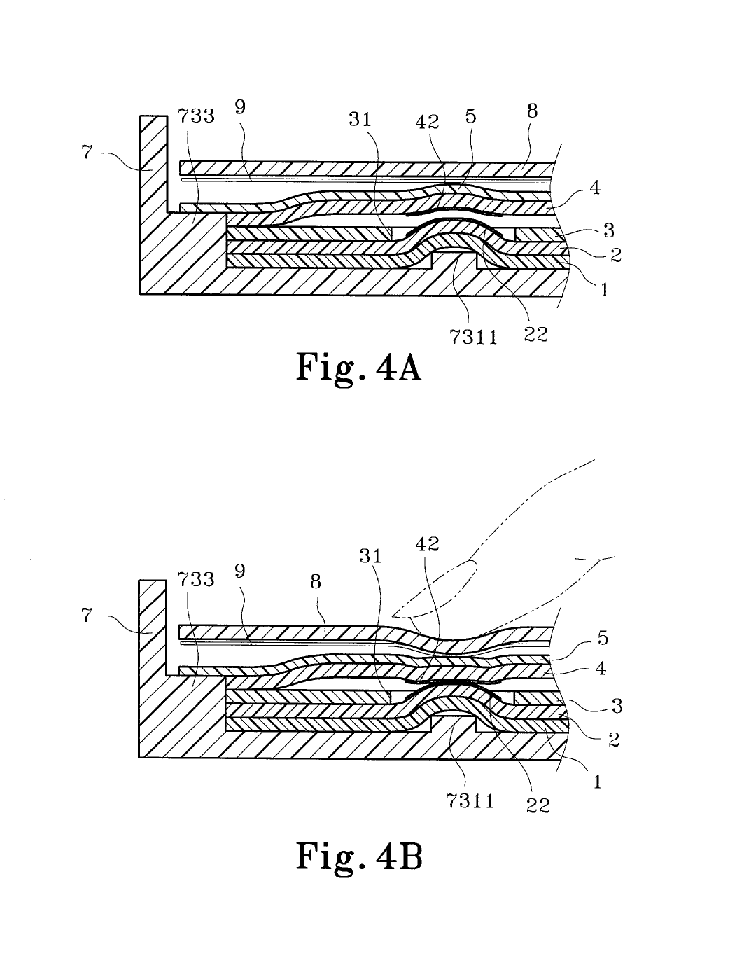

The second conductive membrane layer 2 (silver paste) is located above the bottom layer 1 and has a second conductive circuit (not shown in the figures) and a second conductive section 22 formed thereon (shown in FIG. 4A). The insulation layer 3 is located above the second conductive membrane layer 2 and has a plurality of through openings 31 formed therein. The first conductive membrane layer 4 is located above the insulation layer 3 and has a first conductive circuit (not shown in the figures) and a first conductive section 42 formed thereon. The top layer 5 is located above the first conductive membrane layer 4 and has a selected number of equally spaced folding lines 51 formed thereon. The top layer 5, first and second conductive membrane layer 4 and 2, insulation layer 3 and bottom layer 1 are bonded together around the peripheries by heat fusion to hold the first and second conductive membrane layer 4 and 2 inside, then bond three sides of the transparent membrane layer 8 to the top layer 5 by heat fusion. The bottom layer 1, second conductive membrane layer 2, insulation layer 3, first conductive membrane layer 4 and top layer 5 have respectively a plurality of positioning bores 11, 21, 32, 41 and 51 formed therein mating with the folding lines 51.

This invention further includes a pliable face panel 9 whose surface may have different colors and patterns and be printed with a plurality of key sets 91. The face panel 9 is inserted into the membrane keyboard through the unsealed side of the transparent layer 8 and top layer 5. The face panel 9 may also be printed with various types of patterns or company promotion items and trademarks as background, or have luminescent printing to facilitate operation in darkness and to add flashy and amusing effect.

At one end of the second conductive membrane layer 2, there is a circuit board 63 for an interrupted device 6 which is wired to a button 61 located on the top layer 5. The circuit board 63 has a plurality of positioning apertures 631 and has one end linked to a transmission cable 62 to connect with a computer processor (not shown in the figures) for transmitting keyboard output signals to the computer processor. Thus form a compact membrane keyboard that is foldable for storing and easy to carry around.

The holding case 7 includes a first lid 71, a second lid 72 and a base tray 73. The first lid 71 has first folding section 716 engaged with the second lid 72. The second lid 72 has a second folding section 727 engaged with the base tray 73. The first and second folding section 716 and 727 are mating respectively with the folding lines 51 of the keyboard. The first and second folding section 716 and 727 further have respectively positioning struts 7161 and 7271 to engage with the positioning bores 11, 21, 32, 41, and 51.

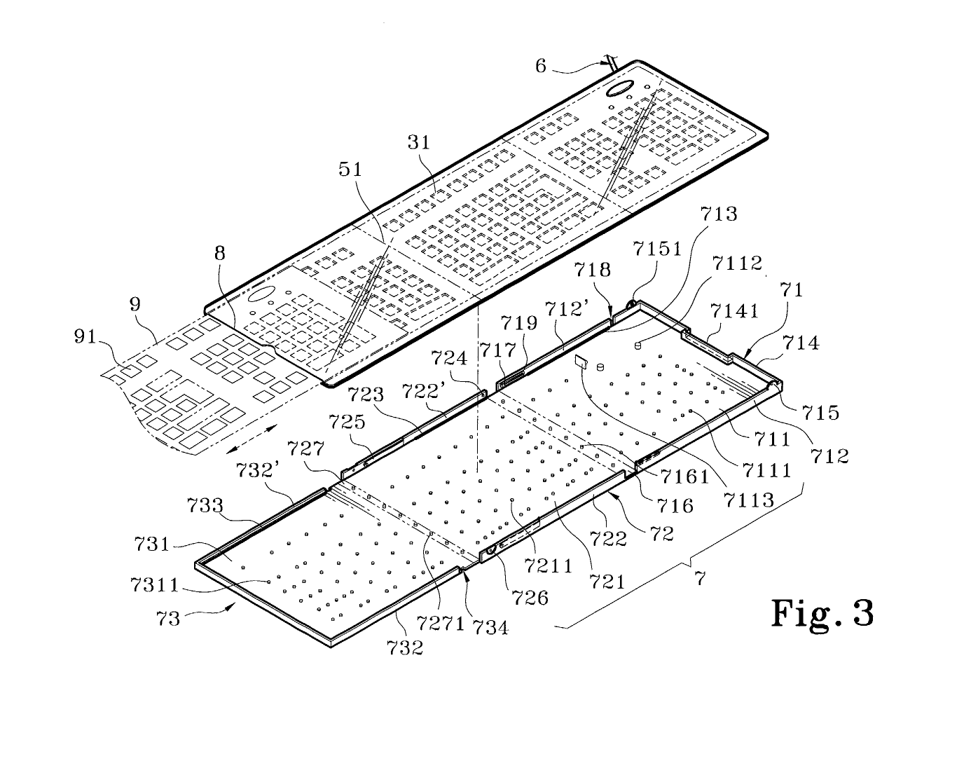

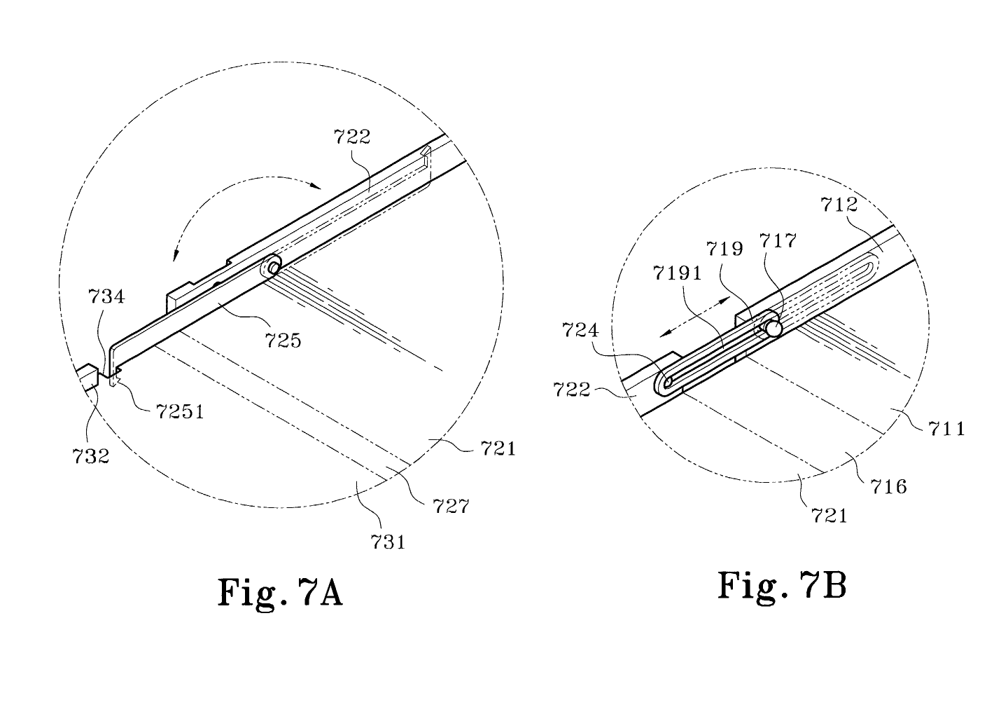

The first lid 71 includes a first compartment 711, two first side walls 712 and 712′ facing each other and an end wall 714. The first compartment 711 has a plurality of protrusive tenons 7111 and positioning tenons 7112 located therein. Adjacent the inner surface of the end wall 714 and first side walls 712 and 712′, there are respectively a stepwise blocks 713. The side first walls 712 and 712′ has respectively a pivot stub 717 mounted thereon. The pivot stub 717 is pivotally engages with a linkage beam 719 which has an elongate slot 7191 formed therein (also shown in FIG. 7B). At one end on the top of the first side walls 712 and 712′, there is respectively a latch member 715 which has a latch stub 7151 located thereon (FIG. 3). At either one of the first side wall 712 or 712′, there is further a cable notch 718 for the cable 62 to pass through. The end wall 714 is located between the first side walls 712 and 712′, and has an indented recess 7141.

The second lid 72 includes a second compartment 721 which has a plurality of protrusive tenons 7211 located therein and two second side walls 722 and 722′ facing each other. The second side walls 722 and 722′ have respectively a stepwise block 723 adjacent the inner surface thereof, a latch bore 726 located at one end thereof for engaging with the latch stub 7151, and a link stub 724 engageable with the slot 7191. Furthermore, at the inner side of the second side walls 722 and 722′, there is a pivotal latch bar 725 which has a latch finger 7251 formed at one end thereof (also shown in FIG. 7A).

The base tray 73 includes a third compartment 731 which has a plurality of protrusive tenons 7311 located therein and two third side walls 732 and 732′ which have respectively a stepwise block 733 adjacent the inner surface thereof. Between the second folding section 727 and the third side walls 732 and 732′, there is a latch slot 734.

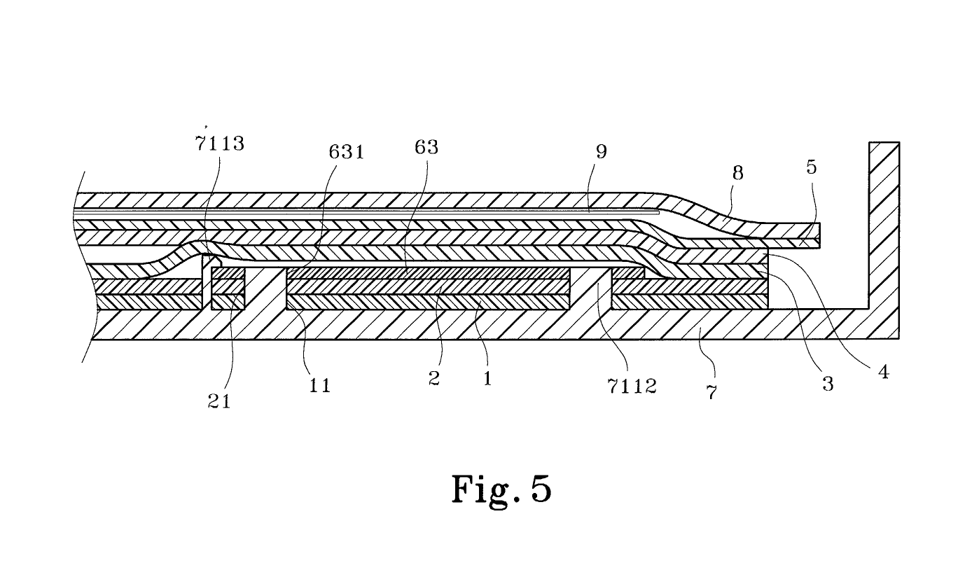

When disposing the keyboard of this invention in the compartments 711, 721 and 731 of the holding case 7, match and engage the positioning bores 11, 21, 32, 41 and 51 with the positioning struts 7161 and 7271; also insert the positioning tenons 7112 into the positioning apertures 631 of the circuit board 63, a latch tenon 7113 located in the first lid (71) will engage with the circuit board 63 securely (also shown in FIG. 5). The transparent membrane layer 8 and top layer 5 thus are resting on the stepwise blocks 713, 723 and 733 (shown in FIG. 4A). Hence the membrane keyboard may be held securely in the holding case 7.

Referring to FIGS. 4A and 4B, when the keyboard is in use, user's finger presses the transparent membrane layer 8, face panel 9 and top layer 5. As the second conductive section 22 is already raised by the protrusive tenons 7111, 7211 and 7311, hence when an external pressing force is applied as set forth above, the first conductive section 42 will be moved across the through opening 31 to contact the second conductive section 22 to output an instruction signal which will be transmitted to the computer processor through the interrupted device 6 (FIG. 1).

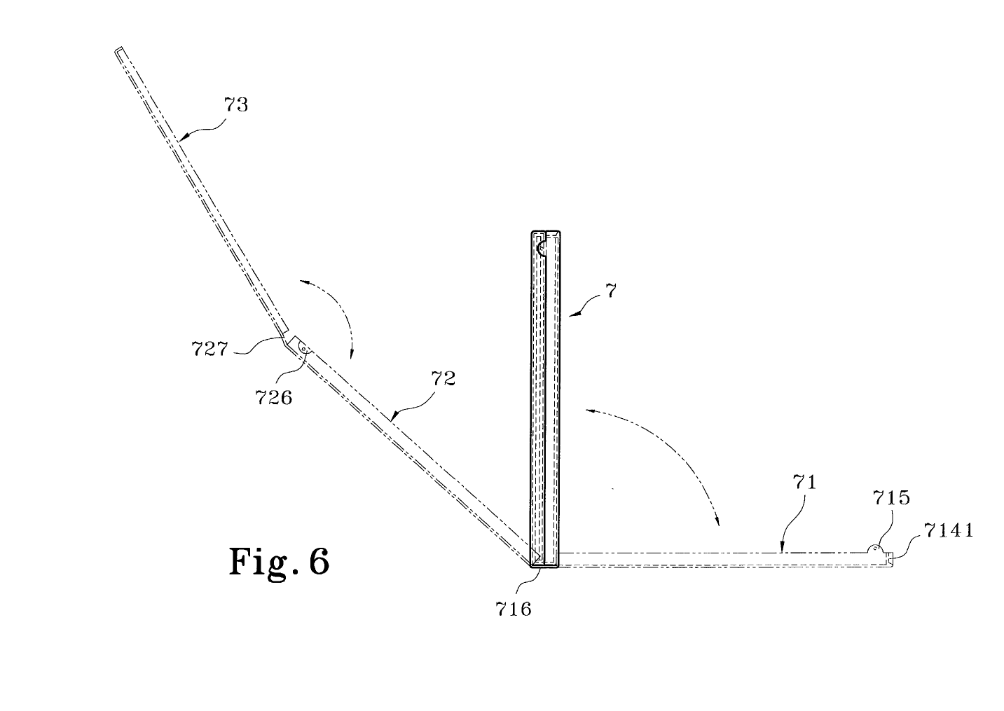

FIG. 6 illustrates this invention is folded and held in the holding case 7. The membrane keyboard is held in the compartments 711, 721, and 731 first; move the base tray 73 toward the second lid 72 about the folding section 727 to put the base tray 73 in the second lid 72; then move the first lid 71 toward the folded base tray 73 about the folding section 716 to make the latch stub 7151 engaging with the latch bore 726. Then the membrane keyboard and the holding case 7 will be folded and packed together concurrently for users to carry around easily.

Referring to FIGS. 7A and 7B, when to open and extend this invention for use, fully open and extend the holding case 7 first; slide the linkage beam 719 of the first lid 71 toward the second lid 72 for the slot 7191 to engage with the link stud 724; then swing the latch bar 725 of the second lid 72 toward the base tray 73 for the latch finger 7251 to engage with the latch slot 734 of the base tray 73. Then the holding case 7 will be extended horizontally and fully and be held firmly for holding the keyboard therein to be used at any location desired.

The bottom layer 1 may be made of a soft material such as foam plastics, soft plastics, leather or the like. The bottom surface of the bottom layer 1 may also formed with an anti-slippery section to prevent the keyboard from slipping during use.

The transmission cable 62 of the interrupt device 6 may be dispensed with and replaced by a wireless transmission circuit located in the interrupted device 6. Then output signals from the keyboard then may be transmitted to the computer processor (not shown in the figures) in wireless fashion.

It may thus be seen that the objects of the present invention set forth herein, as well as those made apparent from the foregoing description, are efficiently attained. While the preferred embodiment of the invention has been set forth for purpose of disclosure, it would be obvious to those skilled in the art that various other changes and modifications can be made according to the embodiment. Accordingly, the appended claims are intended to cover all embodiments which do not depart from the spirit and scope of the invention.

What is claimed is:

1. A foldable membrane keyboard, comprising:
a bottom layer;
a second conductive membrane layer located above the bottom layer;
an insulation layer located above the second conductive membrane layer having a plurality of through openings formed therein;
a first conductive membrane layer located above the insulation layer;
a top layer located above the first conductive membrane layer having a selected number of equally spaced folding lines formed thereon;
a transparent membrane layer located above the top layer;
a soft face panel located between the top layer and transparent membrane layer; and
a holding case;
wherein the top layer, first and second conductive membrane layer, insulation layer and bottom layer are bonded together around the peripheries thereof by heat fusion to hold the first and second conductive membrane layer therein, the transparent membrane layer being bonded to the top layer by heat fusion at three peripheral sides thereof, the bottom layer, second conductive membrane layer, insulation layer, first conductive membrane layer and top layer having respectively a plurality of positioning bores formed therein mating against one another and against the folding lines such that the membrane keyboard is capable of being folded to a compact size for containing in the holding case to facilitate carrying, and when the top layer receiving an external pressing force, the first conductive membrane layer will contact the second conductive membrane layer for output an instruction signal.

2. The foldable membrane keyboard according to claim 1, wherein the top layer is made from a soft and transparent material.

3. The foldable membrane keyboard according to claim 1, wherein the surface of the face panel is printed with a plurality of key sets which are inclined at two ends of the keyboard to conform ergonomics to facilitate users doing data entry.

4. The foldable membrane keyboard according to claim 1, wherein the face panel is selectively printed with background objects including patterns, trademarks or promotional articles.

5. The foldable membrane keyboard according to claim 1, wherein the face panel is printed with a luminescent material which is capable of emitting light in darkness.

6. The foldable membrane keyboard according to claim 1, wherein the bottom layer is made of a soft material selected from the group consisting of a soft foam plastics, a soft plastics or leather.

7. The foldable membrane keyboard according to claim 1, wherein the first and second conductive membrane layers have respectively conductive circuits and conductive section located thereon.

8. The foldable membrane keyboard according to claim 1, wherein the second conductive membrane layer has a circuit board for an interrupted device.

9. The foldable membrane keyboard according to claim 8, wherein the interrupted device connects with a transmission cable linking to a computer processor.

10. The foldable membrane keyboard according to claim 8, wherein the interrupted device includes a wireless transmission circuit for the keyboard to transmit output signals to a computer processor in a wireless transmission fashion.

11. The foldable membrane keyboard according to claim 1, wherein the holding case, includes:
a first lid having a first folding section,
a second lid engageable with the first folding section and having a second folding section, and
a base tray engageable with the second folding section,
wherein the first and second folding section mate respectively with the folding lines of the keyboard and have respectively positioning struts located thereon for engaging with the positioning bores.

12. The foldable membrane keyboard according to claim 11, wherein the first lid includes a first compartment which has a plurality of protrusive tenons and positioning tenons located thereon, and two first side walls which have respectively an inside wall upon which a stepwise block being adjacent thereof and a pivot stub mounted thereon, the pivot stub being pivotally engaged with a linkage beam which has an elongated slot formed therein, the first side walls further having respectively a latch member located on a top side thereof, the latch member having a latch stub located thereon.

13. The foldable membrane keyboard according to claim 11, wherein the second lid includes a second compartment which has a plurality of protrusive tenons and two second side walls which have respectively a second inner surface upon which a stepwise block being adjacent thereof, the second side walls further having respectively a latch bore engageable with the latch stub and a link stub engageable with the elongated slot, the second inner surface further pivotally engaging with a latch bar which has a latch finger formed at one end thereof.

14. The foldable membrane keyboard according to claim 11, wherein the base tray has a base compartment which has a plurality of protrusive tenons located therein and two base side walls which have respectively a base inner surface upon which a stepwise block being adjacent thereof, the base side walls and folding section being interposed with a latch slot therebetween.

15. The foldable membrane keyboard according to claim 12, wherein either of the first side walls has a cable notch for the transmission cable to pass through.

16. The foldable membrane keyboard according to claim 12, wherein the first lid has an end wall located between the first side walls, the end wall having an indented recess for lifting use.
